(19) United States
(12) Patent Application Publication
(10) Pub. No.: US 2006/0267694 A1
(43) Pub. Date: Nov. 30, 2006

(54) VCO with large frequency range but low control voltage gain

(75) Inventor: Brian J. Buell, Gilbert, AZ (US)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Integrated Device Technology, Inc.

(21) Appl. No.: 11/441,264

(22) Filed: May 25, 2006

Related U.S. Application Data
(60) Provisional application No. 60/684,277, filed on May 25, 2005.

(51) Int. Cl. H03L 7/00

(52) U.S. Cl. 331/16

(57) ABSTRACT

A voltage controller oscillator (VCO) circuit is provided for use in a phase-locked loop (PLL) circuit. The VCO circuit has a VCO and a low pass filter. The VCO includes a first input that receives a first voltage control signal from an output of a PLL circuit loop filter, a second input that receives a second voltage control signal, and an output that provides a periodic output signal. The low-pass filter includes an input connected to the output of the PLL circuit loop filter, and an output connected to the second input of the VCO. The first input of the VCO provides high frequency voltage control, and the second input of the VCO provides low frequency voltage control.

### CROSS-REFERENCE TO RELATED APPLICATIONS

This application claims the benefit of U.S. Patent Application No. 60/684,277, filed on May 25, 2005, entitled “VCO with Large Frequency Range But Low Control Voltage Gain.”

### BACKGROUND OF THE INVENTION

A phase locked loop is an electronic circuit that includes a phase detector, low pass filter and voltage-controlled oscillator. The PLL circuit synchronizes an adjustable oscillator with another oscillator by the comparison of phases between the two oscillator signals. It locks itself onto the phase or onto the average frequency of the incoming signal, dynamically tracks it by using a feedback mechanism, and outputs a related but more useful representation of the two signals. For a PLL, it is desirable to have a voltage controlled oscillator with a large frequency range. This allows the VCO to be useful in a large number of applications and compensates for center frequency changes due to process, voltage, and temperature variations. It is also desirable for the VCO to have a low control voltage vs. frequency slope (VCO gain). A low VCO gain is required to minimize the phase jitter of the VCO output signal. In a standard VCO, the VCO gain is equal to:
(frequency range)/(Vₘₐₓ−Vₘᵢₙ).
Since the frequency range and VCO gain are proportional to each other, it is difficult to both maximize the frequency range and minimize the VCO gain.

FIG. 1 shows a prior art PLL block diagram employing a typical VCO having one input port and one output port. FIG. 3 shows a more detailed combination block and schematic diagram of the prior art with the VCO block expanded to show a typical circuit design implementation. The prior art implementation of the VCO shows the use of a single input control voltage for controlling two varactors to adjust oscillator frequency.

### SUMMARY OF THE INVENTION

The present invention has both a large frequency range and a low VCO gain which is produced by making the VCO gain frequency dependent. At low frequencies, the VCO gain is ‘high’ whereas, at high frequencies, the VCO gain is ‘low.’ At a frequency below the bandwidth of the PLL, the VCO gain transitions to a ‘low’ value. The VCO frequency range is equal to:
(VCO gain)×(Vₘₐₓ−Vₘᵢₙ).
The low frequency value of the VCO gain determines the frequency range, so the frequency range is ‘high’.

Phase jitter and PLL stability are mostly affected by the value of the VCO gain near the bandwidth of the PLL. In this region, the VCO gain is ‘low’. Thus, the benefits of both a large frequency range and low VCO gain are achieved.

### BRIEF DESCRIPTION OF THE DRAWINGS

The following drawings provide examples of the invention. However, the invention is not limited to the precise arrangements, instrumentalities, scales, and dimensions shown in these examples, which are provided mainly for illustration purposes only. In the drawings:

FIG. 1 shows a prior art PLL block diagram.

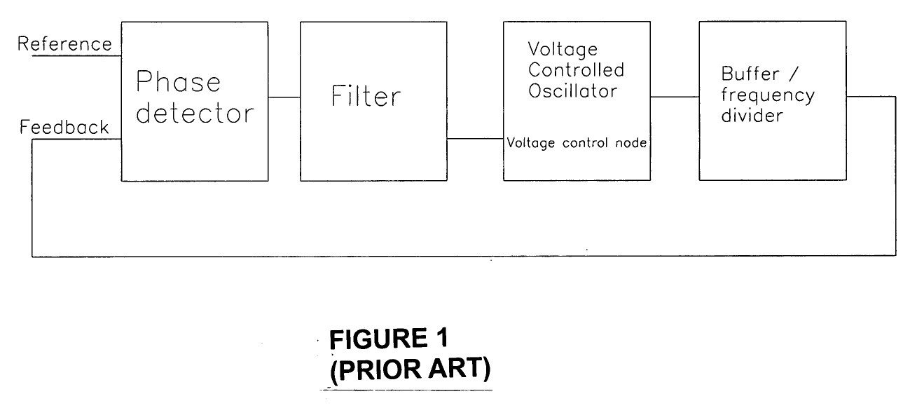

FIG. 2 shows a block diagram of a PLL system in accordance with one preferred embodiment of the present invention.

FIG. 3 shows a more detailed combination block and schematic diagram of the prior art PLL block diagram of FIG. 1.

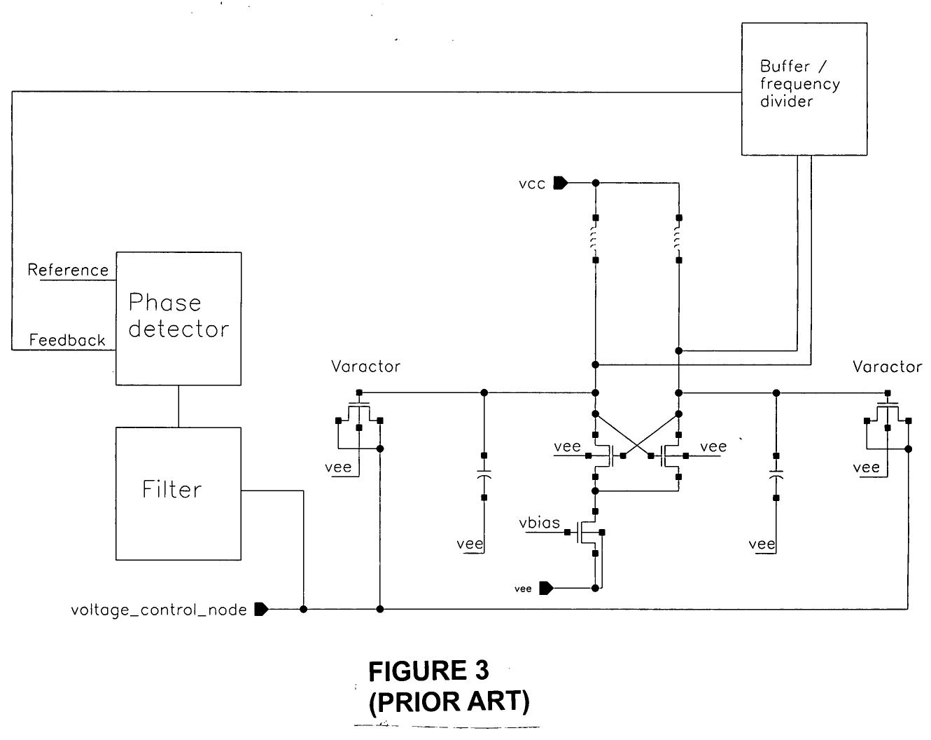

FIG. 4 shows a more detailed combination block and schematic diagram of a PLL system of FIG. 2 in accordance with one preferred embodiment of the present invention.

FIG. 5 shows a comparison of the gain versus frequency plot of a PLL system using a prior art VCO and a VCO of the present invention.

FIG. 6 shows a comparison of the phase versus frequency plot of a PLL system using a prior art VCO and a VCO of the present invention.

### DETAILED DESCRIPTION OF THE INVENTION

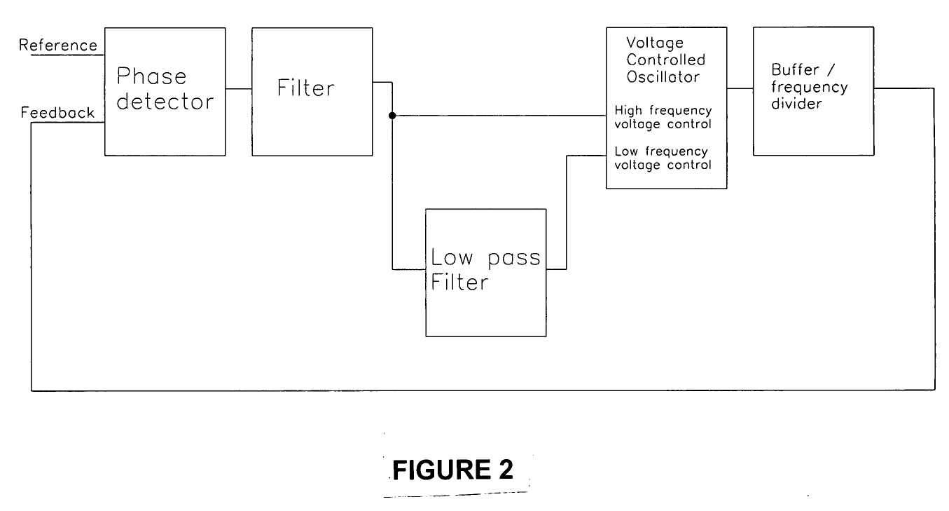

FIG. 2 shows a block diagram of a PLL system in accordance with one preferred embodiment of the present invention. In this embodiment, the VCO and the Low Pass Filter blocks are provided as one integral device. The present invention has two input ports and one output port. The input ports are used for the control voltage of the VCO wherein one is for a high frequency control voltage and the other is for a low frequency control voltage. The output port delivers the desired frequency output of the VCO to the PLL system.

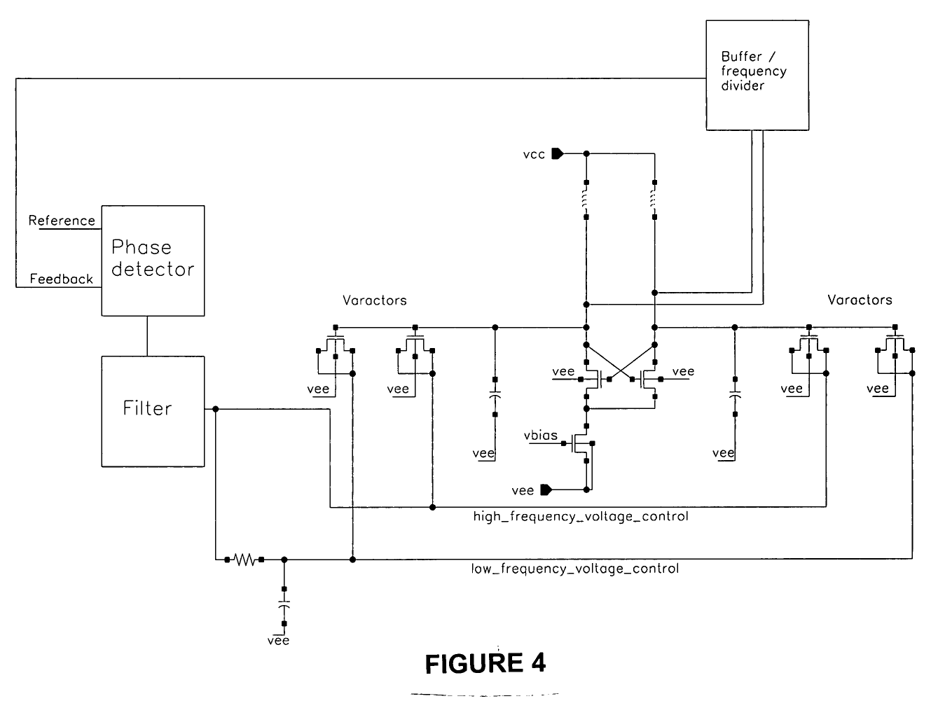

FIG. 4 shows a more detailed combination block and schematic diagram of a PLL system with the VCO block expanded to show the circuit implementation. The VCO of the present invention uses two control voltages, one of which is internally low-pass filtered. The additional low pass filter is an integral part of the present invention and is shown as a 1^{st} order passive low pass filter. However, it could also be implemented as either a higher order passive or active filter.

The VCO uses two additional varactors which are connected to the low frequency control voltage. In addition, the other two varactors are connected to the high frequency control voltage. The low frequency control voltage extends the range of the VCO, without increasing the VCO's susceptibility to unwanted noise from the PLL phase detector and filter path.

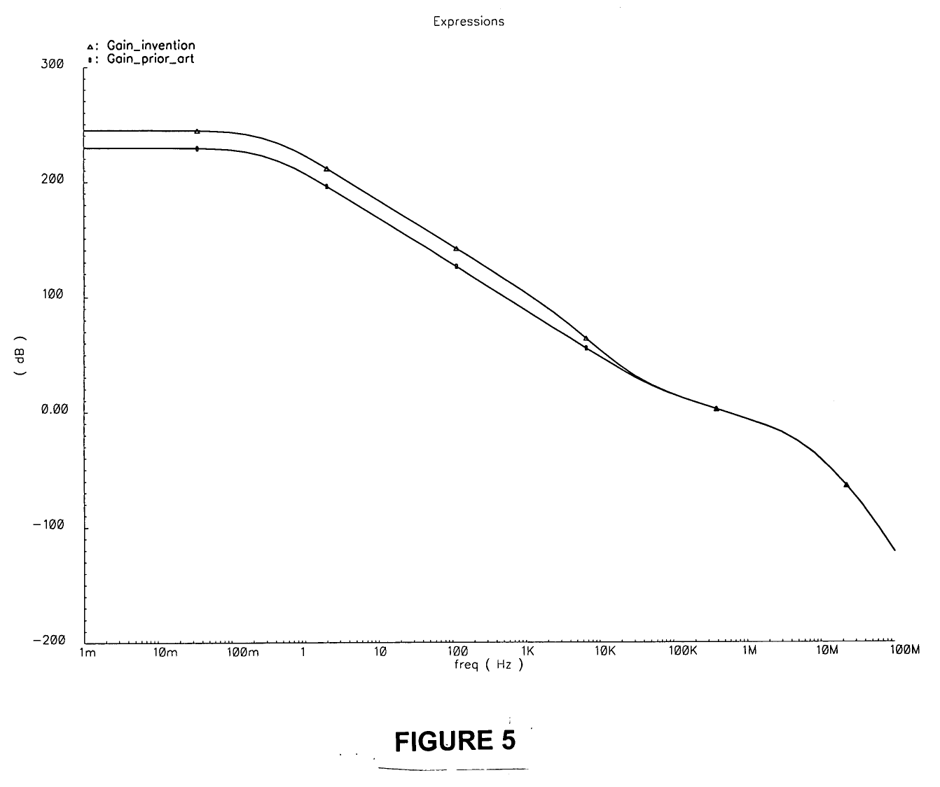

FIG. 5 shows a comparison of the gain versus frequency plot of a PLL system using a prior art VCO and a VCO of the present invention. The plot shows that the present invention has increased gain at lower frequencies over the prior art VCO. However, the gain of both VCO's are the same at higher frequencies. This is a desirable gain response to maintain overall PLL stability.

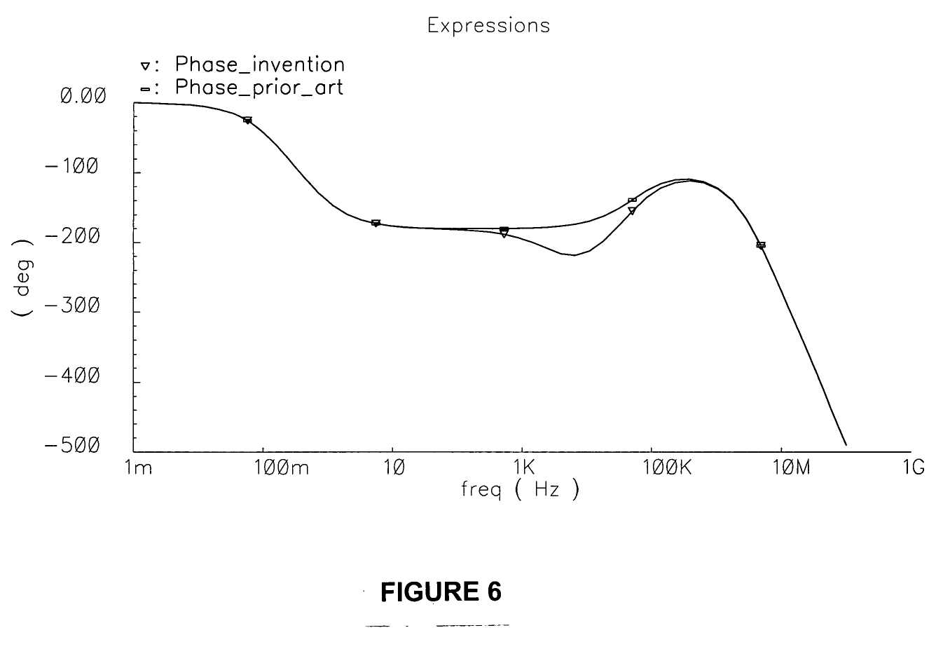

FIG. 6 shows a comparison of the phase versus frequency plot of a PLL system using a prior art VCO and a VCO of the present invention. The plot shows that the phase is similar for both VCO implementations, except near the pole of the added low pass filter. The added low pass filter contributes some phase shift at frequencies below the bandwidth of the PLL, but the phase shift is negligible near the bandwidth of the PLL. Thus, the added low pass filter does not degrade the stability of the PLL.

It will be appreciated by those skilled in the art that changes could be made to the embodiments described above without departing from the broad inventive concept thereof. It is understood, therefore, that this invention is not limited to the particular examples disclosed, but it is intended to cover modifications within the spirit and scope of the present invention as defined by the appended claims.

What is claimed is:

1. A voltage controller oscillator (VCO) circuit for use in a phase-locked loop (PLL) circuit, the VCO circuit comprising:
(a) a VCO including:
(i) a first input that receives a first voltage control signal from an output of a PLL circuit loop filter,
(ii) a second input that receives a second voltage control signal, and
(iii) an output that provides a periodic output signal; and
(b) a low-pass filter including:
(i) an input connected to the output of the PLL circuit loop filter, and
(ii) an output connected to the second input of the VCO,
wherein the first input of the VCO provides high frequency voltage control, and the second input of the VCO provides low frequency voltage control.

2. The VCO circuit of claim 1 wherein the VCO further includes:
(iv) a first pair of varactors connected to the first input of the VCO, the first pair of varactors adjusting the frequency of the VCO based on the first voltage control signal, and
(v) a second pair of varactors connected to the second input of the VCO, the second pair of varactors adjusting the frequency of the VCO based on the second voltage control signal,
wherein the VCO circuit has two halves and each varactor in the pairs is used for a respective half of the VCO circuit.

3. The VCO circuit of claim 2 wherein a common terminal of the varactors in each of the respective pairs has a shared connection with the VCO output.

4. The VCO circuit of claim 3 wherein the common terminal is the gate of each of the varactors.

5. The VCO circuit of claim 2 wherein each of the varactors is a four terminal varactor having a gate terminal connected to the VCO output, source and drain terminals connected to the first or second voltage control signals, and a substrate (bulk) terminal connected to a supply voltage.

6. The VCO circuit of claim 1 wherein the low-pass filter is a first order passive low-pass filter.

7. The VCO circuit of claim I wherein the low-pass filter is an active filter.

8. A voltage controller oscillator (VCO) circuit for use in a phase-locked loop (PLL) circuit, the VCO circuit comprising:
(a) a VCO including:
(i) a first input that receives a first voltage control signal derived from an output of a phase detector,
(ii) a second input that receives a second voltage control signal, and
(iii) an output that provides a periodic output signal; and
(b) a low-pass filter including:
(i) an input connected to the first voltage control signal, and
(ii) an output connected to the second input of the VCO,
wherein the first input of the VCO provides high frequency voltage control, and the second input of the VCO provides low frequency voltage control.

9. The VCO circuit of claim 8 wherein the VCO further includes:
(iv) a first pair of varactors connected to the first input of the VCO, the first pair of varactors adjusting the frequency of the VCO based on the first voltage control signal, and
(v) a second pair of varactors connected to the second input of the VCO, the second pair of varactors adjusting the frequency of the VCO based on the second voltage control signal,
wherein the VCO circuit has two halves and each varactor in the pairs is used for a respective half of the VCO circuit.

10. The VCO circuit of claim 9 wherein a common terminal of the varactors in each of the respective pairs has a shared connection with the VCO output.

11. The VCO circuit of claim 10 wherein the common terminal is the gate of each of the varactors.

12. The VCO circuit of claim 9 wherein each of the varactors is a four terminal varactor having a gate terminal connected to the VCO output, source and drain terminals connected to the first or second voltage control signals, and a substrate (bulk) terminal connected to a supply voltage.

13. The VCO circuit of claim 8 wherein the low-pass filter is a first order passive low-pass filter.

14. The VCO circuit of claim 8 wherein the low-pass filter is an active filter.

15. A phase-locked loop (PLL) circuit comprising:
(a) a voltage controller oscillator (VCO) including:
(i) a first input that receives a first voltage control signal,
(ii) a second input that receives a second voltage control signal, and
(iii) an output that provides a periodic output signal;
(b) a frequency divider connected to the output of the VCO for dividing the output signal of the VCO;
(c) a phase detector including:
(i) a first input that receives the divided VCO signal,
(ii) a second input that receives a reference signal from a reference oscillator, and
(iii) an output,
wherein the phase detector compares the reference signal to the divided VCO signal and generates a phase detector error signal representing the detected phase difference at its output;
(c) a loop filter for filtering the error signal and coupling it to the VCO, the loop filter including:
(i) an input connected to the output of the phase detector for receiving the error signal, and
(ii) an output connected to the first input of the VCO, the output being the first voltage control signal; and
(d) a low-pass filter including:
(i) an input connected to the output of the loop filter, and
(ii) an output connected to the second input of the VCO,
wherein the first input of the VCO provides high frequency voltage control, and the second input of the VCO provides low frequency voltage control.

16. The PLL circuit of claim 15 wherein the VCO further includes:
(iv) a first pair of varactors connected to the first input of the VCO, the first pair of varactors adjusting the frequency of the VCO based on the first voltage control signal, and
(v) a second pair of varactors connected to the second input of the VCO, the second pair of varactors adjusting the frequency of the VCO based on the second voltage control signal,
wherein the VCO circuit has two halves and each varactor in the pairs is used for a respective half of the VCO circuit.

17. The VCO circuit of claim 16 wherein a common terminal of the varactors in each of the respective pairs has a shared connection with the VCO output.

18. The VCO circuit of claim 17 wherein the common terminal is the gate of each of the varactors.

19. The VCO circuit of claim 16 wherein each of the varactors is a four terminal varactor having a gate terminal connected to the VCO output, source and drain terminals connected to the first or second voltage control signals, and a substrate (bulk) terminal connected to a supply voltage.

20. The PLL circuit of claim 15 wherein the low-pass filter is a first order passive low-pass filter.

21. The PLL circuit of claim 15 wherein the low-pass filter is an active filter.
